(19) United States
(12) Patent Application Publication
(10) Pub. No.: US 2009/0032927 A1
(43) Pub. Date: Feb. 5, 2009

(54) SEMICONDUCTOR SUBSTRATES CONNECTED WITH A BALL GRID ARRAY

(75) Inventors: Seung-Woo KIM, Chungcheongnam-do (KR); Seyoung YANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/037,823

(22) Filed: Feb. 26, 2008

(30) Foreign Application Priority Data
Jul. 31, 2007 (KR) 2007-0077177

(51) Int. Cl. H01L 23/02; H01L 21/00

(52) U.S. Cl. 257/686; 438/109; 257/E25.013

(57) ABSTRACT

A stacked module has an upper semiconductor package that includes a substrate having opposed first and second surfaces. A cavity defined in the second surface receives at least a portion of a semiconductor mounted on the substrate of a lower semiconductor package. A plurality of solder bumps disposed between the first and second packages connect the two substrates.

### CROSS-REFERENCE TO RELATED PATENT APPLICATION

This application claims the priority of Korean Patent Application No. 2007-0077177, filed on Jul. 31, 2007, in the Korean Intellectual Property Office, the disclosure of which is incorporated herein in its entirety by reference.

### BACKGROUND OF THE INVENTION

1. Field of the Invention

The present invention relates generally to stacked semiconductor modules and devices incorporating such modules and more particularly to stacked modules formed from substrates that are electrically connected by a ball grid array.

2. Description of the Related Art

As electronic products move to smaller size and larger density and higher performance, semiconductors have correspondingly become smaller with their components and connections becoming denser. This in turn has lead to the development of system in package (SIP) in which a plurality of integrated circuits is enclosed in a single package or module and of package on package (POP) in which separate semiconductor packages are stacked vertically using solder bumps, known as a Ball Grid Array (BGA).

In this type of POP, a dense arrangement of solder bumps is required because an upper semiconductor package is connected via solder bumps to the outer region of a lower semiconductor package. In FIGS. 1 and 2, for example, conventional semiconductor stacked modules, 10 and 12, respectively, have corresponding structure that is identified with the same numeral.

A first package 14 includes a pair of semiconductor chips 16, 18 that are stacked together in a known manner. Semiconductor chip 18 is mounted on a substrate 20 via adhesive and semiconductor chip 16 is mounted on semiconductor chip 18, also via adhesive. Internal circuitry in each chip is connected via wire bonds, some of which are indicated generally at 20, to wiring patterns (not visible) formed in substrate 20. The wiring patterns in turn passes through substrate 20 to connect to a plurality of solder bumps 24. Molding material 26 encapsulates semiconductor chips 16, 18 and wire bonds 22. As a result, internal circuitry in semiconductors 16, 18 is electrically connected to solder bumps 24.

A second package 28 includes a single semiconductor chip, in module 10 of FIG. 1, and a pair of stacked chips, in module 12 of FIG. 2 mounted on a substrate 30. In a fashion similar to module 10, wiring in substrate 30 connects internal circuitry in the semiconductor chip or chips in second package 28 to solder bumps 32 attached to the lower side of the second package.

Additional wiring patterns (not visible) in substrate 30 is also intended to connect solder bumps 24 to solder bumps 32. But problems associated with this type of POP may interfere with providing good electrical connections between first package 14 and second package 28. One such problem arises because solder bumps 24 must be large enough to provide enough space between the top surface of substrate 28 and the bottom surface of substrate 20 to accommodate the height of the semiconductor chip package mounted on substrate 28. As a result the pitch, i.e., distance between the centers of adjacent solder bumps, is limited on the low end because the solder bumps have to be taller than the semiconductor chip package mounted on substrate 28. Using large solder bumps with the smallest possible pitch may lead to short circuits when adjacent solder bumps touch one another.

Another problem relates to precisely sizing solder bumps 24. It is desirable to make them as small as possible to create the smallest pitch. This maximizes the density and therefore the total number of possible connections. But if the bumps are made too small, there may be open circuits between bumps 24 and the electrical connections in substrate 28. This happens when the height of the semiconductor chip package on substrate 28 is greater, even if only slightly, than the height of solder bumps 24.

The present invention addresses these problems as well as improving semiconductor packages and modules in ways that will be apparent to a person of ordinary skill in this art.

### BRIEF DESCRIPTION OF THE DRAWINGS

FIG. 1 is a side view of a conventional art stacked module.

FIG. 2 is a side view of another conventional art stacked module.

FIG. 3 is a side, sectional view of a first semiconductor package according to the invention.

FIG. 4 is a side, sectional view of a first stacked module according to the invention, which incorporates the first semiconductor package of FIG. 3.

FIG. 5 is a side, sectional view of a second stacked module according to the invention, also incorporating the first semiconductor package of FIG. 3.

FIG. 6 is a side, sectional view of a second semiconductor package according to the invention.

FIG. 7 is a side, sectional view of a third stacked module according to the invention, which incorporates the second semiconductor package of FIG. 6.

FIG. 8 is a side, sectional view of a third semiconductor package according to the invention.

FIG. 9 is a side, sectional view of a fourth stacked module according to the invention, which incorporates the third semiconductor package of FIG. 8.

FIG. 10 is a side, sectional view of a fourth semiconductor package according to the invention.

FIG. 11 is a side, sectional view of a fifth stacked module according to the invention, which incorporates the fourth semiconductor package of FIG. 10.

FIG. 12 is a side, sectional view of a sixth stacked module according to the invention, also incorporating the fourth semiconductor package of FIG. 8.

FIG. 13 is a schematic diagram of a card constructed in accordance with the present invention.

FIG. 14 is a schematic diagram of a system constructed in accordance with the present invention.

FIGS. 15 and 16 are side sectional views of one aspect of the fabrication of an exemplary semiconductor package in accordance with the invention.

FIGS. 17 and 18 are side sectional views of an alternative approach to the fabrication aspect shown in FIGS. 15 and 16.

FIGS. 19-21 illustrate the completion of the fabrication of the package and an exemplary stacked module according to the invention.

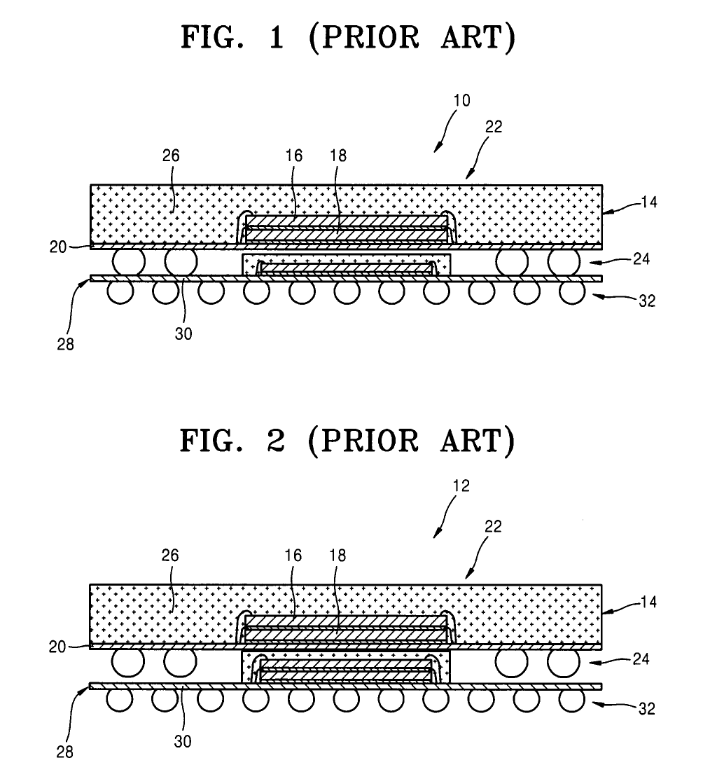

### DETAILED DESCRIPTION

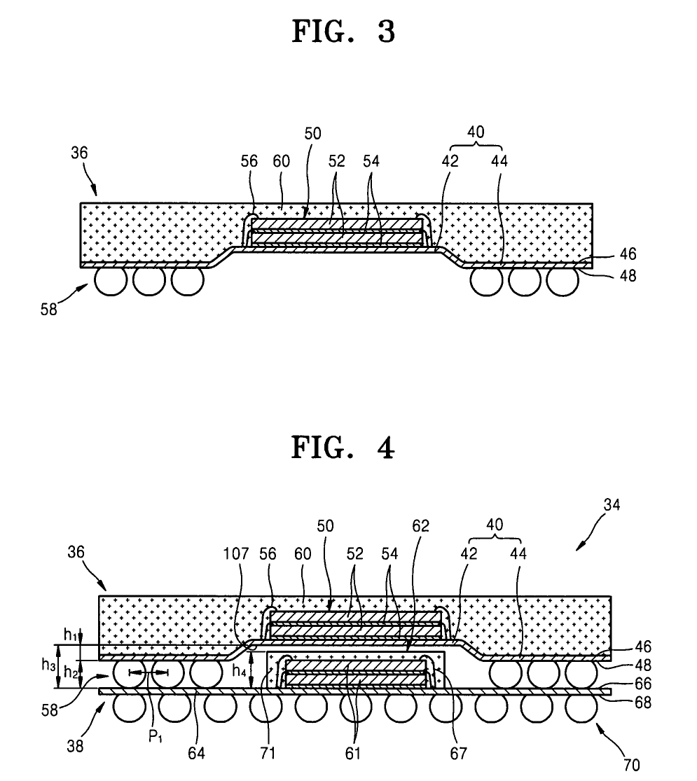

Indicated generally at 36 in FIG. 3 is a semiconductor package constructed in accordance with the present invention. The package 36 includes a first substrate 40 that includes a first portion 42 and a second portion 44. The substrate has a first surface 46 and a second surface 48. The substrate may be made as a printed circuit board or may be constructed from liquid crystal polymer or polyimide. Portions 42, 44 may be made from material that is relatively hard while the portion connecting portions 42, 44 may be made from flexible substrate. Alternatively, as will be explained more fully, all of substrate 40 may be made from a single material that is molded into the shape shown in FIG. 3. The space beneath portion 40 is referred to herein as a cavity.

A first chip set 50 is mounted on a first surface 46 of portion 42 of substrate 40. The first chip set is made up of two semiconductor chips 52. It should be noted that whenever “semiconductor chip” is used herein, it could refer to one or more semiconductor chips, like chips 52, or to a single first chip set incorporating multiple chips. The semiconductor chips 52 are secured to first surface 46 of substrate 40 and to one another via adhesive 54, respectively. Wire bonds, like wire bonds 56, connect terminals on semiconductor chips 52 with wiring patterns (not visible) formed in a known manner either on or in substrate 40. These wiring patterns also connect to solder bumps 58 through substrate 40. Solder bumps 58 are attached to a second surface 48 of substrate 40, which is opposed to first surface 46, and to a corresponding one of the wiring patterns. As a result, there is an electrical connection between bumps 58 and terminals on first chip set 50. Molding material 60 encapsulates first chip set 50 and the wire bonds like wire bonds 56.

Turning now to FIG. 4, indicated generally at 34 is stacked module that incorporates semiconductor package 36. Structure that corresponds to previously identified structure in FIG. 3 is either unnumbered or carries the same identifying number as in FIG. 3. A second semiconductor package 38 includes a second chip set 62 that is constructed generally along the lies of first chip set 50. Second chip set 62 or one of its semiconductor chips is also referred to herein as a second semiconductor chip. Molding material 71 encapsulates second chip set 62 and wire bonds, like wire bonds 67, connect terminals on semiconductor chips 61 with wiring patterns (not visible) formed in a known manner either on or in substrate 64. It should be appreciated that different packages and semiconductor chips could be equally well utilized in stacked module 34. As with semiconductor package 36, terminals on second chip set 62 are connected to wire bonds (as shown), which are in turn connected to wiring patterns (not visible) that are either on or in the surface of a second substrate 64 upon which second chip set 62 is mounted. The second substrate includes first and second surfaces, 66, 68, respectively, with first surface 66 being substantially planar.

The wiring patterns in or on substrate 64 are further connected to additional solder bumps 70 through substrate 64. Additional wiring patterns, also either on or in substrate 64, also connect solder bumps 58 to selected ones of additional solder bumps 70. In other words, solder bumps 70 are ultimately electrically connected to internal circuitry of both first chip set 50 and second chip set 62. The solder bumps 70 may be used to connect semiconductor module 34 to another board, package, module or device.

In FIG. 4, h₁ is indicated as the distance between surface 48 on the second portion 44 of substrate 40 and surface 48 on the first portion 42 of substrate 40. The diameter of solder bumps 58 is substantially h₂, as shown. The distance between surface 66 of substrate 64 and surface 48 on the first portion 42 of substrate 40 is indicated by h₃. It can be seen that h₁ plus h₂ equals h₃. Finally, h₄ is the summed height of second chip set 62 and molding material 71 on top surface of the second chip set 62. Hereinafter, this portion of the second semiconductor package 38 is referred to as the body of the second semiconductor package 38. Additionally, in module 34, h₃ is greater than h₂.

The pitch P₁, in FIG. 4, of solder bumps 58 may be controlled by the magnitude of h₁. Put differently, the larger h₁ is, the smaller the pitch of solder bumps 58 may be. As a result, more connections may be made with less risk of open circuits between solder bumps 58 and substrate 64 and less risk of short circuits that result from adjacent ones of solder bumps 58 touching one another. Although solder bumps 58 are shown as being substantially the same size as additional solder bumps 70, solder bumps 58 could be smaller than solder bumps 70 by increasing h₁. This provides a smaller pitch for solder bumps 58 and therefore higher density and more connections while avoiding the open and short circuits associated with the conventional art.

The semiconductor chips as shown in FIG. 4 can be memory chips or logic chips. For example, first chip set 50 of first semiconductor package 36 can be composed of logic chips and second chip set 62 of second semiconductor package 38 can be composed of memory chips because some kinds of logic chips can be larger than a memory chip. It is preferable that first chip set 50 is larger than second chip set 62, but this is not required. It is possible to construct the semiconductor module with any kind of semiconductor chip or chip combination.

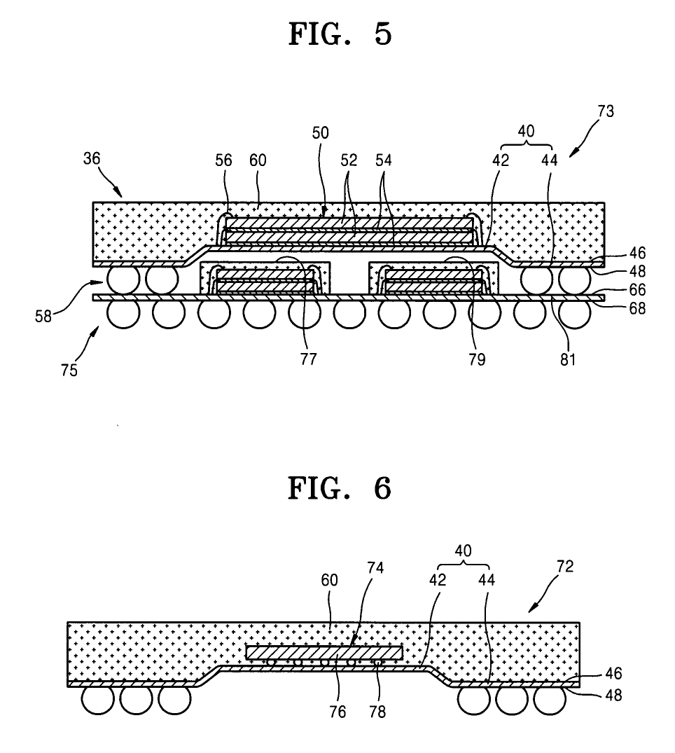

In FIG. 5, indicated generally at 73 is a stacked module that incorporates semiconductor package 36 from FIG. 3. Structure that corresponds to previously identified structure in FIG. 3 is either unnumbered or carries the same identifying number as in FIG. 3. Stacked module 73 includes a second semiconductor package 75 having chip sets 77, 79 mounted on a substrate 81. Chip sets 77, 79 are connected to wiring patterns (not visible) on substrate 81 that are also connected to solder bumps 58 on package 36 and to the solder bumps on the lower surface substrate 81. These connections are made in the same manner as those in the stacked module of FIG. 4.

Turning now to FIG. 6, indicated generally at 72 is another semiconductor package constructed in accordance with the present invention. Structure that corresponds to previously identified structure in FIG. 3 is either unnumbered or carries the same identifying number as in FIG. 3. A flip chip 74 comprises a semiconductor chip 76 that is connected to a wiring pattern in substrate 40 via solder bumps, like solder bump 78.

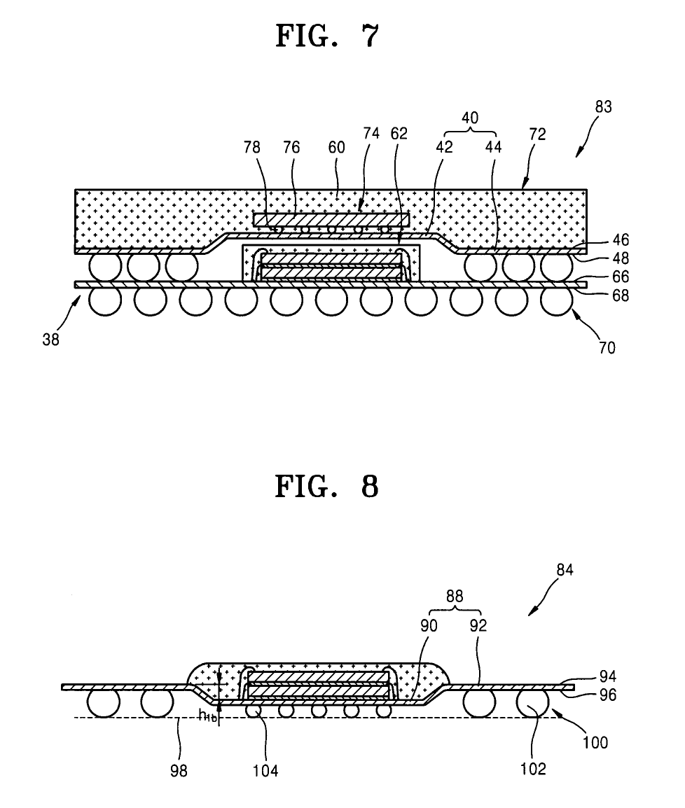

In FIG. 7, another stacked module 83 incorporates semiconductor package 72 from FIG. 6 and semiconductor package 38 from FIG. 4. As with wire bonds 56 in FIG. 3, the solder bumps, like solder bump 78, in FIG. 7 ultimately connect internal circuitry of the flip chip to solder bumps 70 on semiconductor package 38. Also as in FIG. 4, second chip set 62 in semiconductor package 38 is also ultimately connected to solder bumps 70 so that flip chip 74 and second chip set 62 may be connected to another board, package, module or device via solder bumps 70.

An additional semiconductor chip (not shown) can be mounted on the flip chip 74 and electrically connected to the solder bumps 58.

Considering now FIG. 8, another semiconductor package 84 according to the invention includes a substrate 88 having a first portion 90 and a second portion 92. Non-planar portions, as shown, connect first portion 90 and second portion 92. Substrate 88 further includes a first surface 94 and a second surface 96. A dashed line 98 indicates a substantially planar surface upon which additional solder bumps 100 may be electrically connected to another board, package, module or device in a known manner. In FIG. 8, additional solder bumps 100 includes larger solder bumps, like bump 102, beneath second portion 92, and smaller solder bumps, like bump 104, beneath first portion 90. The larger and smaller solder bumps have diameters that result in all of the solder bumps touching the substantially planar surface represented by line 98, as shown. These additional solder bumps 104 provide module 80 with higher density connections and more connections while avoiding the open and short circuits associated with the conventional art.

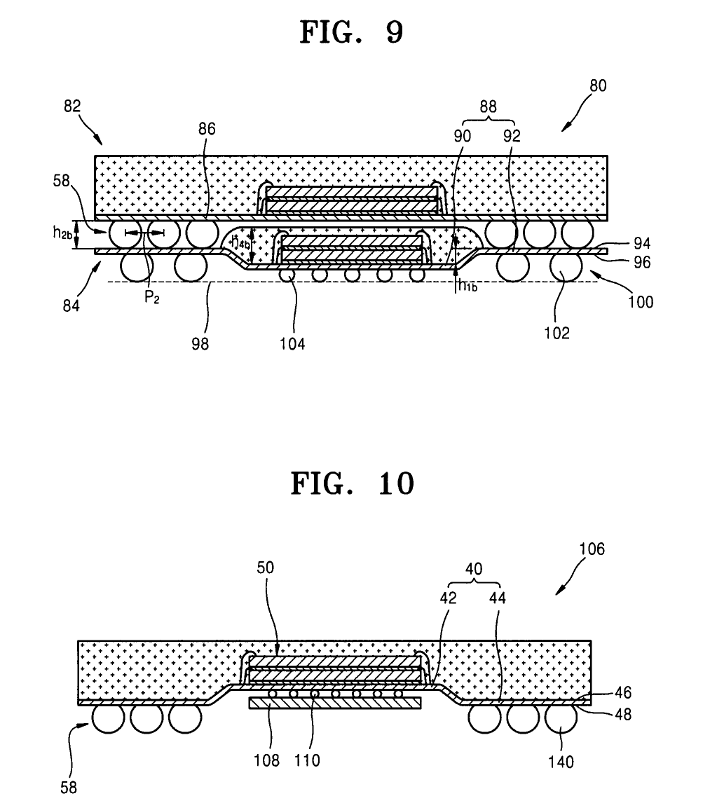

Turning now to FIG. 9, indicated generally at 80 is another stacked module constructed in accordance with the present invention, which incorporates semiconductor package 84 in FIG. 8. Again, structure that corresponds to previously identified structure is either unnumbered or carries the same identifying number. Stacked module 80 includes a first semiconductor package 82 and second semiconductor package 84. The first semiconductor package 82 includes a substantially planar substrate 86. Package 82 is substantially identical to first semiconductor package 36 in FIG. 3 except that substrate 86 in FIG. 5 is substantially planar while substrate 40 in FIG. 3 includes non-planar portions between first portion 42 and second portion 44.

The height of the second semiconductor package body, which is the summed height of second chip set 91 and molding material 93 on substrate 88, is indicated in FIG. 9 as h_{4b}. The distance between the first surface on second portion 92 of substrate 88 and the lower surface of the substrate in first semiconductor package 82 is designated as h_{2b}. And the distance between first surface 94 on first portion 90 of substrate 88 and the first surface 94 on the second portion 92 of substrate 88 is shown in FIG. 9 as h_{1b}. The greater h_{1b} is, the smaller h_{2b} may be. As shown in the drawing h_{2b} may be smaller than h_{4b}. As h_{2b} becomes smaller, the pitch P₂ between adjacent ones of the solder bumps may become smaller while the risk remains low for short circuits between adjacent solder bumps and for open circuits between the solder bumps and substrate 88. This smaller pitch for solder bumps 58 provides the first semiconductor package 82 with higher density connections and more connections while avoiding the open and short circuits associated with the conventional art.

In FIG. 10, indicated generally at 106 is a semiconductor package constructed in with the present invention. As with previous figures, structure that corresponds to previously identified structure is either unnumbered or carries the same identifying number. Package 106 is similar to package 36 in FIG. 3 except that a flip chip 108 is attached to surface 48 on the first portion 42 of substrate 40 via solder bumps, like solder bump 110. As with first chip set 50, wiring patterns (not visible) formed in a known manner either on or in substrate 40 connect the flip chip solder bumps with solder bumps 58.

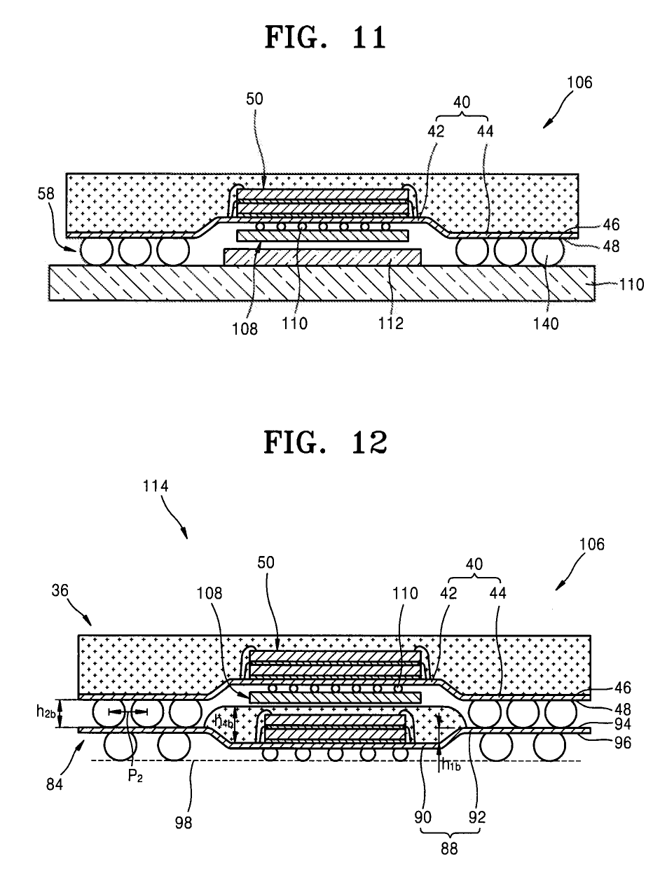

In FIG. 11, solder bumps 58 are in turn connected to a wiring pattern (not visible) formed on or in a board 110. In other words, all of the necessary electrical connections for first chip set 50 and flip chip 108 are made via solder bumps 58. Board 110 has an electronic component 112 mounted thereon. The wiring pattern on the board may make connections between first chip set 50 and/or flip chip 108 and component 112. The electronic component can be a resistor, inductor, capacitor or an electronic device having an electronic circuit. This embodiment also increases device density and decreases device size.

Indicated generally at 114 in FIG. 12 is another stacked module constructed in accordance with the present invention. The stacked module includes a first semiconductor package 36, which is generally the same as package 36 in FIG. 3, and a second semiconductor package 84, which is generally the same as second semiconductor package 84 in FIG. 9. As with previous figures, structure that corresponds to previously identified structure is either unnumbered or carries the same identifying number. As a result of the respective shapes of substrates 40, 88, there is enough space to accommodate both the second chip set 91 and flip chip 108 between the two substrates. All of the electrical connections that need to be made to flip chip 108, first chip set 50, and second chip set 91 on substrate 88 are ultimately made via additional solder bumps 100 in the manner described above.

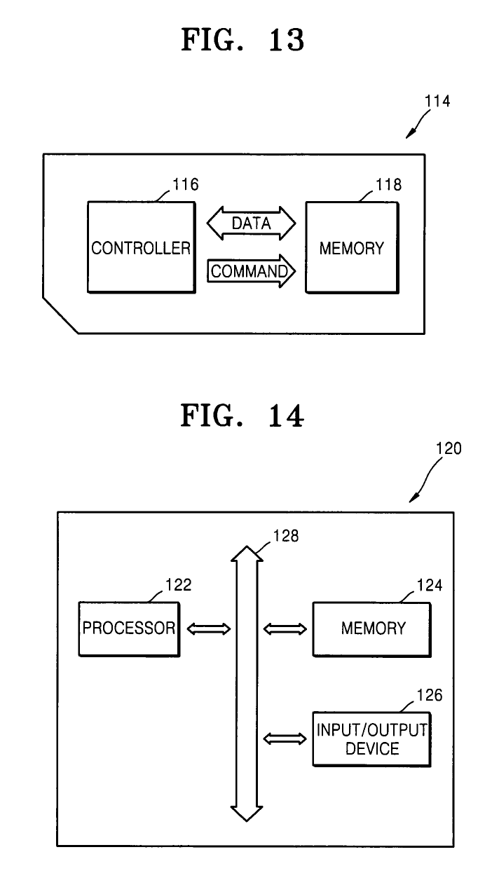

Turning now to FIG. 13, indicated generally at 114 is a schematic diagram of a card constructed in accordance with the present invention. Card 114 may be, e.g., a multimedia card (MMC) or a secure digital card (SD). Card 114 includes a controller 116 and a memory 118, which could be a DRAM, flash, PRAM, or another type of memory. A communication channel, indicated generally at 120, permits the controller to provide commands to the memory and to transfer data into and out of memory 118. Controller 116 and memory 118 may comprise a BGA chip set in accordance with any of the previously described embodiments.

The card 114 can have a larger density than a conventional card. In FIG. 3, it is possible to remove solder bumps 70 and form external terminals (not shown) for the card on the second surface 68 of substrate 64. This means that substrate 64 of second semiconductor package 38 can be used as a card substrate. All of the embodiments of the present invention can be similarly adapted for use in a card.

Considering now FIG. 14, indicated generally at 120 is a system constructed in accordance with the present invention. System 120 may be, e.g., a mobile phone, an MP3 player, a GPS navigation device, a solid state disk (SSD), a household appliance, etc. System 120 includes a processor 122; a memory 124, which could be a DRAM, flash, PRAM, or another type of memory; and an Input/Output Device 126. A communication channel 128 permits the processor to provide commands to the memory to transfer data into and out of memory 124 via channel 128. Data and commands may be transferred to and from system 120 via Input/Output device 126. Processor 122 and memory 124 may comprise a BGA chip set in accordance with any of the previously described embodiments. The present invention can reduce the volume of system 120 as a result of reduced volume of electronic devices as compared to conventional art having the same number of connections.

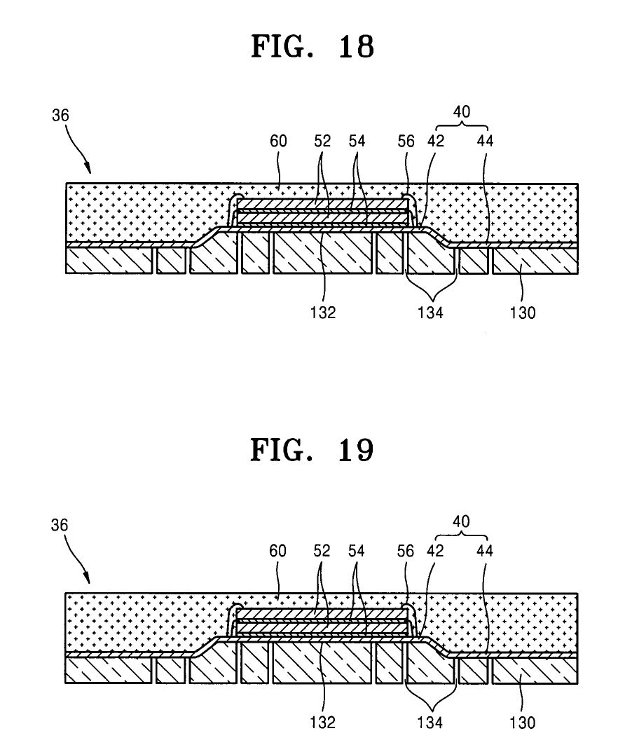

Consideration will now be given to how embodiments of the present invention are manufactured. In FIG. 18, semiconductor package 36 is substantially the same as semiconductor package 36 in FIG. 3 and includes corresponding identifying numerals on some of the structure. Semiconductor package 36 is positioned on top of a mold 130 that includes a protruding region 132, which defines first substrate portion 42, second substrate portion 44, and the transition therebetween. A plurality of bores 134 communicate with a pump (not shown) that provides a vacuum to the underside of substrate 40.

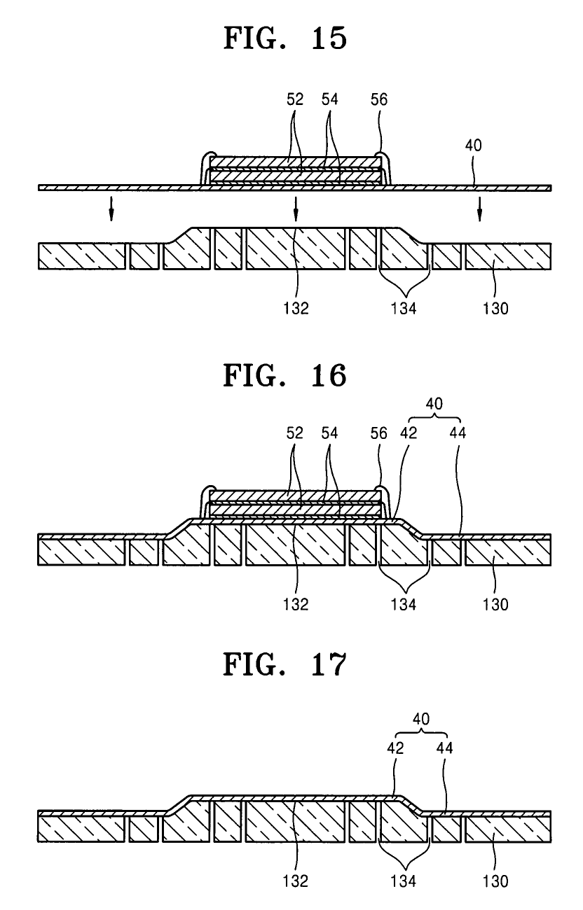

There are at least two possible approaches to arriving at the stage of the manufacturing process illustrated in FIG. 18. In the first approach, with reference to FIG. 15, semiconductor devices 52 are attached to substantially planar substrate 40 via adhesive 54 and wire bonds 56. Semiconductor devices 52 may also be connected to one another using flip chip bonding or through-silicon via (TSV) technology. The substantially planar substrate is then positioned above mold 130, as shown in FIG. 15, and a press (not shown) presses the substrate into the form shown in FIG. 16. In addition, or alternatively, vacuum applied via bores 134 may further draw the substrate into the shape of the mold as shown in FIG. 16.

In the second approach, with reference to FIG. 17, substantially planar substrate 40 without any components mounted thereon is positioned over mold 130 and pressed or drawn into the shape shown in FIG. 17 using the vacuum applied to bores 134. Thereafter semiconductor devices 52 are attached to substrate 40 via adhesive 54 and wire bonds 56. As with the first approach, semiconductor devices 52 may be connected to one another using, e.g., flip chip bonding or through-silicon via (TSV) technology.

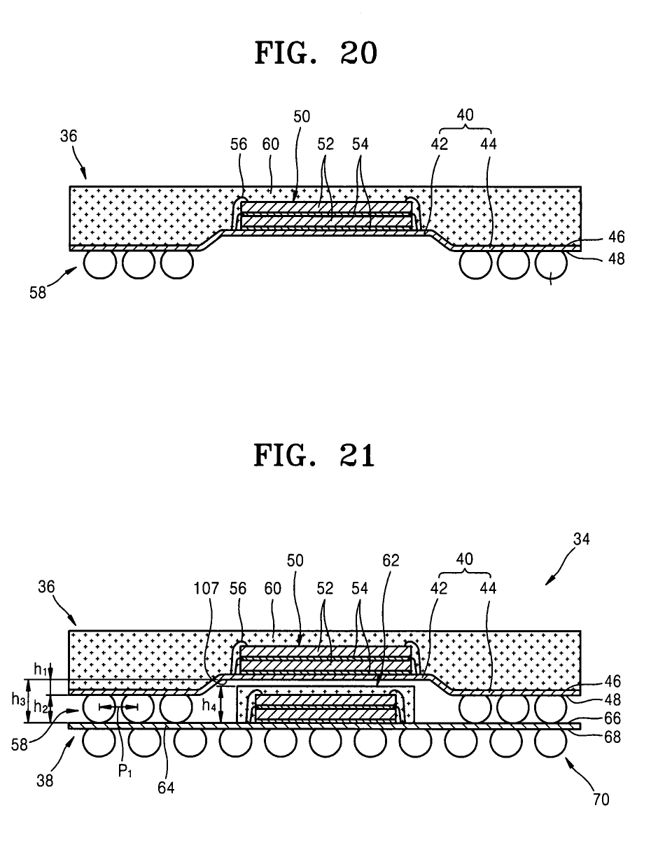

Next, regardless of which of the two approaches is used, the semiconductor devices 52 are encapsulated with molding material 60, as shown in FIG. 18, and substrate 40 is removed from mold 130. Then solder bumps, like solder bumps 58 in FIG. 20, are formed on the underside of substrate 40. These may be formed by first disposing the solder bumps on the substrate and then reflowing the solder bumps to attach them to the underside of substrate 40 as shown in FIG. 3.

Finally, solder bumps 58 are disposed on second semiconductor package 38 in FIG. 21, and a reflow process is performed on bumps 58 to attach the semiconductor packages as shown in FIG. 21.

As a result, there is an improved stacked module comprising a package over another package or over a semiconductor device or devices mounted on a board, card or other substrate. The diameter of the solder bumps on the package may be reduced thus increasing the pitch while lowering the risk of short circuits between adjacent solder bumps and open circuits between the solder bumps and their corresponding contacts. This facilitates increasing the total number of electrical connections made by the solder bumps.

What is claimed is:

1. A semiconductor stacked module comprising:
a first substrate having opposed first and second surfaces;
a cavity defined by the second surface of the substrate;
a first semiconductor chip mounted on the first surface opposite the cavity;
a second substrate having opposed first and second surfaces;
a second semiconductor chip mounted on the first surface of the second substrate; and
a plurality of solder bumps formed between the second surface of the first substrate and the first surface of the second substrate, the solder bumps connecting the two substrates with the second semiconductor chip being received at least partly within the cavity.

2. The semiconductor stacked module of claim 1 further comprising electrical connections formed between the solder bumps and terminals formed on the first semiconductor device.

3. The semiconductor stacked module of claim 1 wherein the module is constructed and arranged for mounting on a substantially planar surface and wherein the semiconductor stacked module further comprises additional solder bumps formed between the second surface of the second substrate and the substantially planar surface when the module is so mounted.

4. The semiconductor stacked module of claim 3 wherein all of the solder bumps are substantially the same size.

5. The semiconductor stacked module of claim 3 wherein the solder bumps formed between the second surface of the first substrate and the first surface of the second substrate are smaller than the additional solder bumps formed between the second surface of the second substrate and the substantially planar surface .

6. The semiconductor stacked module of claim 3 wherein the pitch of the solder bumps formed between the second surface of the first substrate and the first surface of the second substrate is less than the pitch of the additional solder bumps.

7. The semiconductor stacked module of claim 1 wherein the height of the second semiconductor chip is greater than the height of the solder bumps.

8. The semiconductor stacked module of claim 1 wherein the first semiconductor chip comprises a flip chip.

9. The semiconductor stacked module of claim 1 further comprising a third semiconductor chip mounted on the second surface in the cavity.

10. A semiconductor stacked module comprising:
a first substrate having opposed first and second surfaces;
a cavity defined by the second surface of the first substrate;
a second substrate having opposed first and second surfaces;
a cavity defined by the first surface of the second substrate;
at least one semiconductor chip mounted on the surface by which one of the cavities is defined;
a plurality of solder bumps formed between the second surface of the first substrate and the first surface of the second substrate, the solder bumps connecting the two substrates with the cavities substantially opposite one another.

11. The semiconductor stacked module of claim 10 further comprising a second semiconductor chip mounted on the first surface of the first substrate opposite the cavity defined by the second surface of the first substrate.

12. The semiconductor stacked module of claim 11 wherein the at least one semiconductor chip is mounted the cavity defined by the second surface of the first substrate and wherein the semiconductor stacked module further comprises a third semiconductor chip mounted on the first surface of the second substrate in the cavity.

13. The semiconductor stacked module of claim 10 wherein the module is constructed and arranged for mounting on a substantially planar surface and wherein the module further comprises additional solder bumps formed between the second surface of the second substrate and the substantially planar surface when the module is so mounted.

14. The semiconductor stacked module of claim 13 wherein additional solder bumps beneath the cavities are smaller than additional solder bumps that are not beneath the cavities.

15. A semiconductor package mountable on a substantially planar surface comprising:
a substrate having opposed first and second surfaces, the second surface facing the substantially planar surface when the package is mounted thereon;
a substantially planar first portion of the substrate that is spaced away from the substantially planar surface by a first distance when the package is mounted on the substantially planar surface;
a substantially planar second portion of the substrate adjacent the first portion of the substrate, the second portion of the substrate being spaced away from the substantially planar surface by a second distance different from the first distance when the package is mounted on the substantially planar surface; and
at least one semiconductor chip mounted on the first surface of the first portion of the substrate.

16. The semiconductor package of claim 15 wherein the first distance is greater than the second distance.

17. The semiconductor package of claim 15 wherein the first distance is less than the second distance.

18. The semiconductor package of claim 17 wherein the substrate is constructed and arranged to have a second semiconductor package mounted on the first surface of the substantially planar second portion of the substrate via solder bumps and wherein the height of the at least one semiconductor chip is greater than the height of the solder bumps when the second semiconductor package is so mounted.

19. The semiconductor package of claim 15 wherein the semiconductor chip comprises a flip chip.

20. The semiconductor package of claim 15 further comprising a second semiconductor chip mounted on the second surface of the first portion of the substrate.

21. The semiconductor package of claim 15 further comprising a plurality of solder bumps mounted on the second surface of the second portion of the substrate.

22. The semiconductor package of claim 21 further comprising a plurality of electrical connections between the semiconductor chip and the solder bumps.

23. The semiconductor package of claim 15 further comprising a plurality of solder bumps mounted on the second surface of the second portion of the substrate for attaching the package to a board, the bumps spacing the package away from the board by an amount sufficient for the second surface of the first portion to clear a component mounted on the board beneath the second surface of the first portion when the package is so attached.

24. A memory card comprising:
a first substrate having opposed first and second surfaces;
a cavity defined by the second surface of the substrate;
a first semiconductor chip mounted on one of the surfaces;
a second substrate having opposed first and second surfaces;
a second semiconductor chip mounted on the first surface of the second substrate, one of the semiconductor chips comprising a memory and the other comprising a controller; and
a plurality of solder bumps formed between the second surface of the first substrate and the first surface of the second substrate, the solder bumps connecting the two substrates with the second semiconductor chip being received at least partly within the cavity.

25. An electronic system comprising:
a first substrate having opposed first and second surfaces;
a cavity defined by the second surface of the substrate;
a first semiconductor chip mounted on one of the surfaces;
a second substrate having opposed first and second surfaces;
a second semiconductor chip mounted on the first surface of the second substrate, one of the semiconductor chips comprising a memory and the other comprising a processor;
a plurality of solder bumps formed between the second surface of the first substrate and the first surface of the second substrate, the solder bumps connecting the two substrates with the second semiconductor chip being received at least partly within the cavity; and
an input/output device to transfer information to and from the system.

26. A method for making a semiconductor package comprising:
positioning a substantially planar substrate over a mold having a substantially planar first surface that is spaced away from the substrate by a first distance and a substantially planar second surface that is adjacent the first surface and spaced away from the substrate by a second distance;
pressing the substrate into the mold until the substrate assumes the shape of the mold surfaces;
mounting at least one semiconductor chip on one side of the substrate; and
mounting solder bumps on the other side of the substrate.

27. The method of claim 26 further comprising forming a plurality of electrical connections between the solder bumps and the at least one semiconductor chip.

28. The method of claim 26 further comprising mounting at least one additional semiconductor chip on the other side of the substrate.

29. The method of claim 26 wherein the first distance is greater than the second distance.

30. The method of claim 26 wherein the first distance is less than the second distance.

31. The method of claim 26 wherein the method further comprises using the solder bumps to mount the substrate on another substrate.

32. The method of claim 26 wherein mounting at least one semiconductor chip on one side of the substrate comprises mounting the at least one semiconductor chip on the one side via solder bumps.

33. The method of claim 26 wherein the solder bumps are mounted on a portion of the substrate that is shaped by one of the mold surfaces.

34. The method of claim 33 wherein the solder bumps are mounted on a portion of the substrate that is shaped by both of the mold surfaces.

35. The method of claim 34 further comprising using solder bumps of one size on the portion shaped by the first mold surface and using solder bumps of a different size on the portion shaped by the second mold surface.
